(19) United States
(12) Patent Application Publication
(10) Pub. No.: US 2024/0145294 A1
(43) Pub. Date: May 2, 2024

(54) METHOD FOR MANUFACTURING A SILICON-CARBIDE-BASED SEMICONDUCTOR STRUCTURE AND INTERMEDIATE COMPOSITE STRUCTURE

(71) Applicant: Soitec, BERNIN (FR)

(72) Inventors: Hugo Biard, Bernin (FR); Gweltaz Gaudin, Bernin (FR)

(21) Appl. No.: 18/548,616

(22) PCT Filed: Mar. 3, 2022
(86) PCT No.: PCT/FR2022/050380

§ 371 Date: Sep. 1, 2023

(30) Foreign Application Priority Data
Mar. 9, 2021 (FR) FR2102307

(51) Int. Cl. H01L 21/762; H01L 21/02

(52) U.S. Cl. CPC H01L 21/76254; H01L 21/02444; H01L 21/02529

(57) ABSTRACT

A method for manufacturing a semiconductor structure comprises: a) providing a temporary substrate comprising a material having a coefficient of thermal expansion close to that of silicon carbide; b) forming an intermediate graphite layer on a front face of the temporary substrate; c) depositing, on the intermediate layer, a polycrystalline silicon carbide support layer having a thickness of between 10 microns and 200 microns, d) transferring a useful monocrystalline silicon carbide layer onto the support layer in order to form a composite structure, the transfer using molecular adhesion bonding, e) forming an active layer on the useful layer, and f) disassembling, at an interface of or inside the intermediate layer, to structure to form the semiconductor structure including the active layer, the useful layer and the support layer. A composite structure is obtained by the method.

### CROSS REFERENCE TO RELATED APPLICATIONS

This application is a national phase entry under 35 U.S.C. § 371 of International Patent Application PCT/FR2022/050380, filed Mar. 3, 2022, designating the United States of America and published as International Patent Publication WO 2022/189733 A1 on Sep. 15, 2022, which claims the benefit under Article 8 of the Patent Cooperation Treaty to French Patent Application Serial No. FR2102307, filed Mar. 9, 2021.

### TECHNICAL FIELD

The present disclosure relates to the field of semi-conductor materials for microelectronic components. In particular, it relates to a method for manufacturing a semiconductor structure comprising an active layer made of high-quality monocrystalline silicon carbide comprising or intended to receive electronic components, the active layer being disposed on a support layer made of polycrystalline silicon carbide. The present disclosure also relates to an intermediate composite structure obtained during the method.

### BACKGROUND

Interest in silicon carbide (SiC) has increased considerably in recent years, as this semi-conductor material can increase energy processing capacity. SiC is increasingly used for manufacturing innovative power devices in order to meet the needs of growing areas of electronics, such as electric vehicles in particular.

Power devices and integrated power supply systems based on monocrystalline silicon carbide can manage much higher power density than their traditional silicon equivalents, and with smaller active area dimensions. In order to further limit the dimensions of power devices on SiC, it is advantageous for vertical components to be manufactured rather than lateral components. To this end, vertical electrical conduction between an electrode disposed on the front face of the assembly of components and an electrode disposed on the rear face must be allowed by the assembly.

Bulk substrates made of monocrystalline SiC intended for the microelectronics industry nevertheless remain expensive and difficult to source in large sizes. Furthermore, when it is produced on a bulk substrate, the assembly of electronic components often requires the rear face of the substrate to be thin, typically around 100 microns, in order to reduce the vertical electrical resistivity and/or to meet space and miniaturization specifications.

It is therefore advantageous for thin layer transfer solutions to be used in order to produce composite structures typically comprising a thin layer made of monocrystalline SiC on a lower cost support substrate, with the thin layer being used to form the electronic components. A well known thin layer transfer solution is the Smart Cut™ method, which is based on light ion implantation and assembly by direct bonding. Such a method allows, for example, a composite structure to be manufactured that comprises a thin layer made of monocrystalline SiC (c-SiC), taken from a donor substrate made of c-SiC, in direct contact with a support substrate made of poly-crystalline SiC (p-SiC), and allowing vertical electrical conduction. The support substrate, which must be thick enough to be compatible with the formation of the components, is finally thinned in order to obtain the assembly of electronic components that is ready to be integrated. Even if the support substrate is of lower quality, the thinning steps and the loss of material are still cost contributors that preferably are to be eliminated.

U.S. Pat. No. 8,436,363 describes a method for manufacturing a composite structure comprising a thin layer made of c-SiC disposed on a metal support substrate, the thermal expansion coefficient of which matches that of the thin layer. This manufacturing method comprises the following steps:
forming a buried brittle plane in a donor substrate made of c-SiC, defining a thin layer between the buried brittle plane and a front surface of the donor substrate;
depositing a metal layer, for example, made of tungsten or of molybdenum, onto the front surface of the donor substrate in order to form the support substrate that is thick enough to act as a stiffener;
separating along the buried brittle plane in order to form, on the one hand, the composite structure comprising the metal support substrate and the thin layer made of c-SiC and, on the other hand, the remainder of the donor substrate made of c-SiC.

The disadvantage of this approach is that a metal support substrate is not always compatible with the lines for manufacturing electronic components. The support substrate also may need to be thinned, depending on the applications.

### BRIEF SUMMARY

The present disclosure relates to an alternative solution to those of the prior art, and aims to overcome all or some of the aforementioned disadvantages. In particular, it relates to a method for manufacturing a semiconductor structure for electronic components, advantageously vertical components, produced on and/or in an active layer made of high-quality monocrystalline silicon carbide, which is disposed on a support layer made of polycrystalline silicon carbide. The present disclosure also relates to a composite structure obtained in an intermediate step of the manufacturing method.

The present disclosure relates to a method for manufacturing a semiconductor structure, comprising:
a) a step of providing a temporary substrate made of a material with a thermal expansion coefficient ranging between 3.5×10⁻⁶/° C. and 5×10⁻⁶/° C.;
b) a step of forming an intermediate layer made of graphite on a front face of the temporary substrate;
c) a step of depositing, onto the intermediate layer, a support layer made of polycrystalline silicon carbide, the thickness of which ranges between 10 microns and 200 microns;
d) a step of transferring a useful layer made of monocrystalline silicon carbide onto the support layer, directly or via an additional layer, in order to form a composite structure, the transfer implementing molecular adhesion bonding;
e) a step of forming an active layer on the useful layer;
f) a removal step, at an interface of the intermediate layer or in the intermediate layer, in order to obtain, on the one hand, the semiconductor structure including the active layer, the useful layer and the support layer, and, on the other hand, the temporary substrate.

According to further advantageous and non-limiting features of the present disclosure, taken individually or according to any technically feasible combination:
the thickness of the intermediate layer ranges between 1 micron and 100 microns;
the average grain size of the graphite of the intermediate layer ranges between 1 micron and 50 microns;
the porosity of the graphite of the intermediate layer ranges between 6 and 17%;
the graphite of the intermediate layer has a thermal expansion coefficient ranging between 4×10⁻⁶/° C. and 5×10⁶/° C.;
in step b), the intermediate layer is also formed on a peripheral edge of the temporary substrate, and/or a second intermediate layer is formed on a rear face of the temporary substrate;
in step c), the support layer is also deposited onto an intermediate layer present on the peripheral edge of the temporary substrate and/or directly onto the peripheral edge of the temporary substrate;
the transfer step d) comprises:
   introducing light species into a donor substrate made of monocrystalline silicon carbide, in order to form a buried brittle plane defining, with the front face of the donor substrate, the useful layer;
   assembling the front face of the donor substrate on the support layer, directly or via an additional layer, by molecular adhesion bonding;
   separating along the buried brittle plane in order to transfer the useful layer onto the support layer;
separation occurs during heat treatment at a temperature ranging between 800° C. and 1,200° C.;
step e) comprises epitaxial growth of at least one additional layer made of doped monocrystalline silicon carbide on the useful layer, the additional layer forming all or some of the active layer;
step e) comprises heat treatment at a temperature above or equal to 1,600° C., intended to cause the activation of dopants in the active layer;
the method comprises a step e′) of producing all or some of the electronic components on and/or in the active layer, with step e′) being placed between step e) and step f);
a detachable handle is assembled on the free face of the active layer or of all or some of the electronic components if they are present, prior to the removal step f);
the removal involved in step f) occurs by propagating a crack at an interface of the intermediate layer or in the intermediate layer, following the application of a mechanical stress;
the removal involved in step f) comprises lateral chemical etching of all or some of the intermediate layer;
the removal involved in step f) comprises thermal damage to the graphite of the intermediate layer;
the removal involved in step f) occurs by cutting the graphite of the intermediate layer using a diamond wire saw;
the method comprises a step of recycling the temporary substrate originating from step f);
step c) comprises depositing, onto the second intermediate layer present on the rear face of the temporary substrate, a second support layer made of polycrystalline silicon carbide, the thickness of which ranges between 10 microns and 200 microns;
step d) comprises transferring a second useful layer made of monocrystalline silicon carbide onto the second support layer, directly or via an additional layer, the transfer implementing molecular adhesion bonding;
step e) comprises forming a second active layer on the second useful layer;
step f) comprises removal, at an interface of the second intermediate layer or in the second intermediate layer, in order to obtain another semiconductor structure including the second active layer, the second useful layer and the second support layer.

The present disclosure also relates to a composite structure comprising:
a temporary substrate made of a material with a thermal expansion coefficient that is close to that of silicon carbide;
an intermediate layer made of graphite, at least disposed on the front face of the temporary substrate;
a support layer made of polycrystalline silicon carbide with a thickness ranging between 10 microns and 200 microns, disposed on the intermediate layer;
a useful layer made of monocrystalline silicon carbide, disposed on the support layer.

According to further advantageous and non-limiting features of the present disclosure, taken individually or according to any technically feasible combination:
the temporary substrate is made of monocrystalline or polycrystalline silicon carbide;
the thickness of the useful layer ranges between 100 nm and 1,500 nm.

### BRIEF DESCRIPTION OF THE DRAWINGS

Further features and advantages of the present disclosure will become apparent from the following detailed description of the present disclosure with reference to the attached figures, in which:

FIG. 1 shows an assembly of electronic components produced in accordance with a manufacturing method according to the present disclosure;

FIGS. 2A, 2B, 2C, 2D, 2E, 2E′, 2F and 2G show steps of a manufacturing method according to the present disclosure;

FIGS. 3A-3D show steps of a particular embodiment of the manufacturing method according to the present disclosure; and

FIGS. 4A-4C show a transfer step d) of the manufacturing method according to the present disclosure.

The same reference signs in the figures can be used for elements of the same type. The figures are schematic representations, which, for the sake of readability, are not to scale. In particular, the thicknesses of the layers along the z-axis are not to scale with respect to the lateral dimensions along the x- and y-axes; and the relative thicknesses of the layers with respect to one another have not necessarily been respected in the figures.

### DETAILED DESCRIPTION

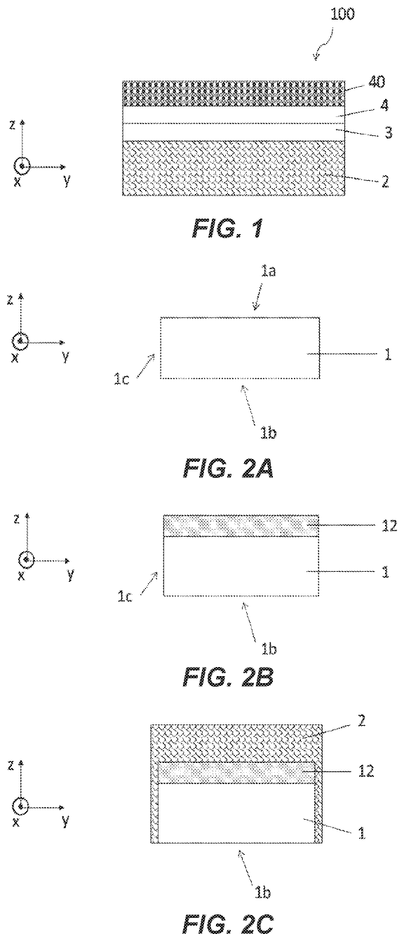

The present disclosure relates to a method for manufacturing a semiconductor structure 100 (FIG. 1). A semiconductor structure 100 is understood to mean at least a stack of layers 4, 3, 2 intended to receive a plurality of microelectronic components; it is also understood to mean the stack of layers 4, 3, 2 with the electronic components 40, which originate from collective manufacturing on and/or in the active layer 4, retained in the form of a wafer by a support layer 2, and ready to undergo the singularization steps before being packaged.

The manufacturing method is advantageously applicable to vertical microelectronic components, which require vertical electrical conduction through the support layer 2, which forms the mechanical support of the components 40.

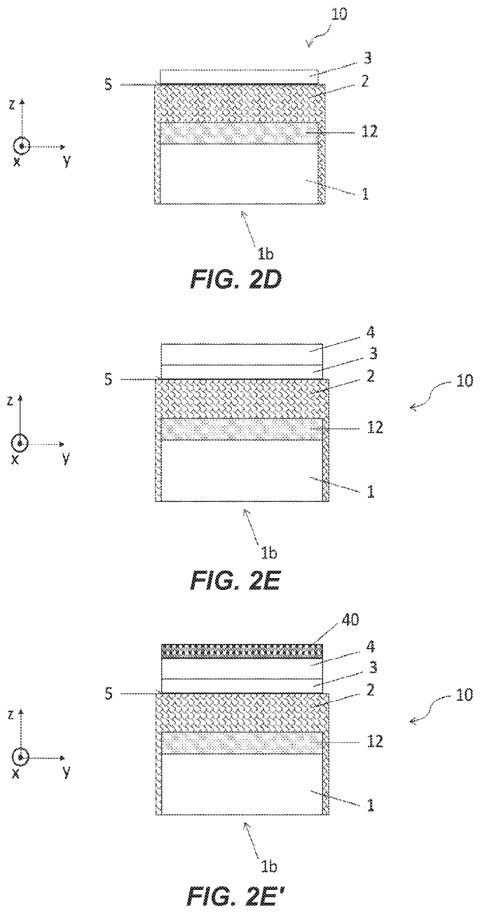

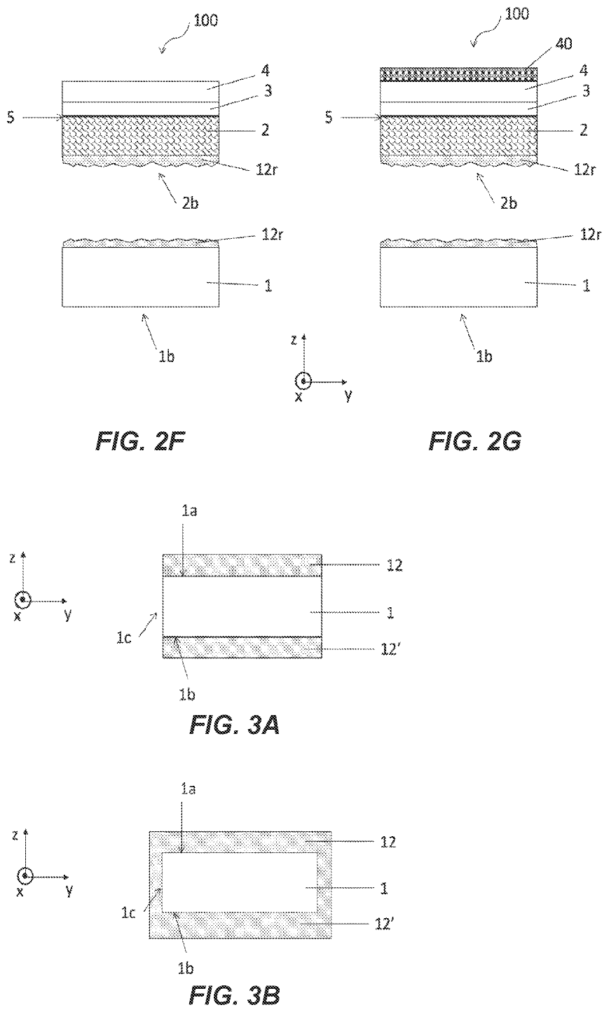

The manufacturing method first comprises a step a) of providing a temporary substrate 1 made of a material, the thermal expansion coefficient of which is close to that of silicon carbide (SiC), namely ranging between 3.5×10⁻⁶/° C. and 5×10⁻⁶/° C. (between the ambient temperature and 1,000° C.), having a front face 1a, a rear face 1b and a peripheral edge 1c (FIG. 2A). Preferably, the temporary substrate 1 is therefore made of polycrystalline or monocrystalline SiC with low crystalline quality, with the role of the temporary substrate 1 being essentially mechanical.

Other materials compatible with the stated thermal expansion coefficient constraint can be used. These materials also need to be compatible with very high temperatures, namely up to approximately 1,850° C., taking into account the subsequent heat treatments provided in the method.

The manufacturing method then comprises a step b) of forming an intermediate layer 12 made of graphite. The intermediate layer 12 can be produced, for example, by plasma deposition, ion spraying, cathodic arc deposition, laser graphite evaporation, carbonization and/or pyrolysis of a resin, etc.

Advantageously, some physical properties of the graphite, set forth hereafter, are selected so as to provide an excellent seed for depositing a layer made of polycrystalline silicon carbide (p-SiC), hereafter called support layer 2, and which will be described with reference to step c) of the method. In particular, the graphite, which has a polycrystalline structure, has a grain size, in particular an average grain size, ranging between 1 micron and 50 microns, i.e., falling within the same order of magnitude as the average grain size expected for the support layer 2, in the plane of the faces 1a, 1b.

It should be noted that the average grain size particularly corresponds to the arithmetic mean of the grain sizes that are greater than or equal to 100 nm. These grain sizes can be measured, for example, by scanning microscopy (SEM), by X-ray diffraction (in particular from the mid-height width of an X-ray diffraction signal) or by electron backscatter diffraction (EBSD).

The thermal conductivity of the support layer 2 is thus ensured, as the grains of the layer will not be too small; moreover, even if the grain size is made to grow when the support layer 2 is deposited, this is still within a controlled size range, due to the defined range of grain sizes of graphite, which limits the roughness on the free surface of the deposited support layer 2.

The porosity of the graphite ranges between 6 and 17%, which is a limited range that allows the surface roughness of the support layer 2 to be controlled after it is deposited. Typically, the surface roughness can be limited to less than 1 micron RMS, or even to less than 10 nm RMS, so as to reduce any smoothing treatments after the support layer 2 is deposited.

The thermal expansion coefficient of the intermediate layer 12 ranges between 4×10⁻⁶/° C. and 5×10⁻⁶/° C. (between the ambient temperature and 1,000° C.), so as to match the thermal expansion coefficient of the silicon carbide, in order to limit mechanical stresses during treatments (subsequently described in the method) involving high temperatures.

The temporary substrate 1 provided with the intermediate layer 12 is compatible with temperatures ranging up to 1,450° C., when the atmosphere is controlled, i.e., without oxygen. Indeed, if exposed to air, the graphite of the intermediate layer 12 starts to burn in a low temperature range, typically 400° C.-600° C. Protected by a protective layer that completely encapsulates it, the intermediate layer 12 made of graphite is compatible with very high temperatures, even above 1,450° C.

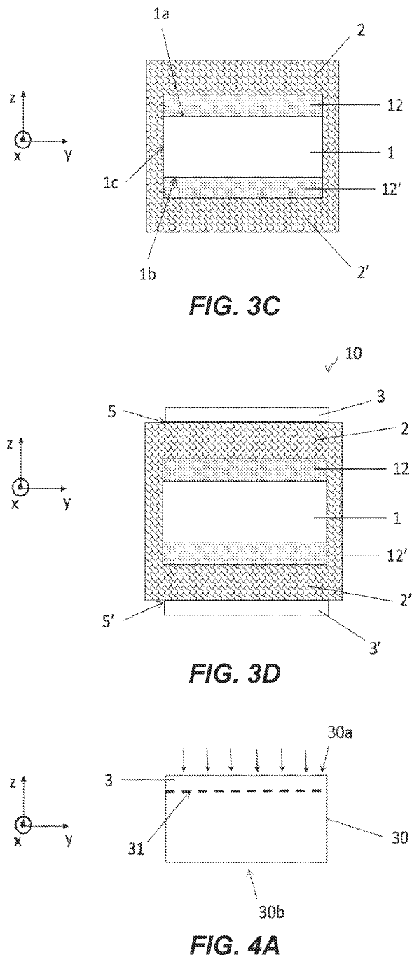

According to a particular embodiment of the method, step b) also comprises forming the intermediate layer 12 on the peripheral edges 1c of the temporary substrate 1 (FIG. 3B). Step b) can also comprise a second intermediate layer 12′ made of graphite, on a rear face 1b of the temporary substrate 1 (FIG. 3A, FIG. 3B), with or without an intermediate layer 12 on the peripheral edges 1c.

With further reference to the general description of the method, a step c) of depositing a support layer 2 made of polycrystalline silicon carbide (p-SiC) onto the intermediate layer 12 is subsequently carried out (FIG. 2C). In particular, the support layer 2 is deposited directly onto the intermediate layer 12, i.e., no additional layer is interposed between layers 2 and 12, which are in contact with each other. Advantageously, the support layer 2 is also deposited onto the peripheral edges 1c of the temporary substrate 1, so as to encapsulate and protect the intermediate layer 12 for the subsequent steps of the method.

The deposition can be carried out using any known technique, in particular by chemical vapor deposition (CVD), at a temperature on the order of 1,100° C. to 1,400° C. For example, a thermal CVD technique such as atmospheric pressure CVD (APCVD) or low pressure CVD (LPCVD) can be cited, with the precursors being able to be selected from methylsilane, dimethyldichlorosilane or even dichlorosilane+i-butane. A plasma enhanced CVD (PECVD) technique also can be used, with, for example, silicon tetrachloride and methane as precursors; preferably, the frequency of the source used to generate the electrical discharge creating the plasma is on the order of 3.3 MHz, and more generally ranges between 10 kHz and 100 GHz.

Prior to deposition, conventional cleaning sequences can be applied to the temporary substrate 1 provided with the intermediate layer 12, in order to remove all or some of the particulate, metal or organic contaminants potentially present on its free faces 1a, 1b.

The thickness of the support layer 2 made of p-SiC ranges between 10 microns and 200 microns. This thickness is selected as a function of the thickness specifications expected for the semiconductor structure 100. The support layer 2 will, in this structure 100, assume the role of a mechanical substrate and will potentially have to ensure vertical electrical conduction. In order to guarantee the aforementioned electrical conduction property (low resistivity), the support layer 2 is advantageously n- or p-type doped as required.

According to the previously mentioned particular embodiment, the deposition of step c) also can be carried out on the second intermediate layer 12′, in order to form a second support layer 2′, and/or on the peripheral edge 1c of the temporary substrate 1, as illustrated in FIG. 3C. The role of the second support layer 2′, deposited onto the rear face 1b of the temporary substrate 1, is to allow the following steps of the method to be carried out on the two faces 1a, 1b of the substrate 1.

In general, after the support layer 2 (and potentially the second support layer 2′) has been deposited, a surface treatment is carried out in order to improve the surface roughness of the support layer 2 and/or the quality of the edges of the structure, with a view to the next thin layer transfer step.

Conventional chemical etching (wet or dry) and/or mechanical grinding and/or chemical-mechanical polishing techniques can be implemented to achieve a surface roughness of the p-SiC that is on the order of 0.5 nm RMS, preferably less than 0.3 nm RMS (roughness measurement using atomic force microscopy—AFM, on a 20 micron×20 micron scan, for example). The aforementioned features of the graphite of the intermediate layer 12 nevertheless allow the surface treatments to be applied to be limited.

Then, the manufacturing method according to the present disclosure comprises a step d) of transferring a useful layer 3 made of monocrystalline silicon carbide (c-SiC) directly onto the support layer 2 or via an additional layer, in order to form a composite structure 10 (FIG. 2D). The transfer implements molecular adhesion bonding, and consequently a bonding interface 5. The additional layer can be formed on the side of the useful layer 3 and/or on the side of the support layer 2, in order to promote the bonding.

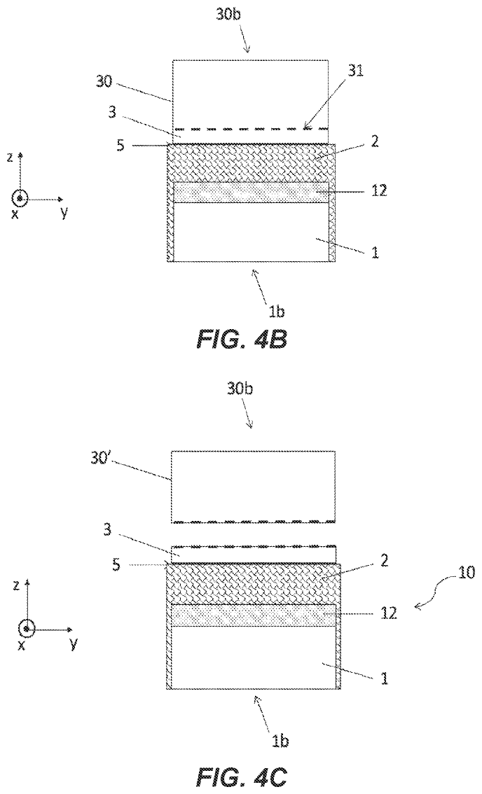

Advantageously, and as is known with reference to the Smart Cut™ method, the transfer step d) comprises:
introducing light species into a donor substrate 30 having a front face 30a and a rear face 30b and made of monocrystalline silicon carbide, in order to form a buried brittle plane 31, defining, with the front face 30a of the donor substrate 30, the useful layer 3 (FIG. 4A);
assembling the front face 30a of the donor substrate 30 on the support layer 2, directly or via an additional layer, by molecular adhesion bonding, along a bonding interface 5 (FIG. 4B); and
separating along the buried brittle plane 31 in order to transfer the useful layer 3 to the support layer 2 (FIG. 4C).

The light species are preferably hydrogen, helium or a co-implantation of these two species, and are implanted in the donor substrate 30 at a determined depth, consistent with the thickness of the intended useful layer 3 (FIG. 4A). These light species will form, around the determined depth, microcavities distributed as a thin layer parallel to the free surface 30a of the donor substrate 30, that is parallel to the (x, y) plane in the figures. This thin layer is called the buried brittle plane 31, for the sake of simplicity.

The implantation energy of the light species is selected so as to reach the determined depth. For example, hydrogen ions will be implanted at an energy level ranging between 10 keV and 250 keV, and at a dosage level ranging between 5^{E}16/cm² and 1^{E}17/cm², in order to define a useful layer 3 with a thickness on the order of 100 to 1,500 nm. It should be noted that a protective layer can be deposited onto the front face 30a of the donor substrate 30, prior to the ion implantation step. This protective layer can be made up of a material such as silicon oxide or silicon nitride, for example. It can be retained for the next step, or be removed.

The donor substrate 30 is assembled on the support layer 2 at the respective front/free faces thereof and forms a bonded stack along the bonding interface 5 (FIG. 4B). As is well known per se, molecular adhesion bonding does not require an adhesive material, as bonds are established at the atomic level between the assembled surfaces. Several types of molecular adhesion bonding exist, which particularly differ in terms of the temperature, pressure, atmosphere conditions or treatments prior to bringing the surfaces into contact. Ambient temperature bonding with or without prior plasma activation of the surfaces to be assembled, atomic diffusion bonding (ADB), surface-activated bonding (SAB), etc., may be employed.

The assembly step can comprise, before bringing the faces to be assembled into contact, conventional cleaning, surface activation or other surface preparation sequences likely to promote the quality of the bonding interface 5 (low defect density, good adhesion quality).

As already mentioned, the front face 30a of the donor substrate 30 and/or the free face of the support layer 2 optionally can comprise an additional layer, for example, a metal (tungsten, etc.) or doped semiconductor (silicon, etc.) layer in order to promote vertical electrical conduction, or an insulating layer (silicon oxide, silicon nitride, etc.) for applications not requiring vertical electrical conduction. The additional layer is likely to promote molecular adhesion bonding, in particular by erasing residual roughness or surface defects present on the faces to be assembled. It can undergo planarization or smoothing treatments in order to achieve roughness of less than 1 nm RMS, or even less than 0.5 nm RMS, which is favorable for bonding.

Separation along the buried brittle plane 31 usually occurs by applying a heat treatment at a temperature ranging between 800° C. and 1,200° C. (FIG. 4C). Such a heat treatment causes cavities and microcracks to develop in the buried brittle plane 31, and their pressurization by the light species present in gaseous form, until a fracture propagates along the brittle plane 31. Alternatively, or jointly, a mechanical stress can be applied to the bonded assembly, and in particular to the buried brittle plane 31, so as to propagate or assist the mechanical propagation of the fracture leading to the separation. On completion of this separation, the composite structure 10 comprising the temporary substrate 1, the intermediate layer 12 made of graphite, the support layer 2 made of p-SiC and the transferred useful layer 3 made of c-SiC is obtained, on the one hand, and the remainder 30′ of the donor substrate is obtained, on the other hand. The useful layer 3 is typically between 100 nm and 1,500 nm thick. The level and type of doping of the useful layer 3 is defined by the selection of the properties of the donor substrate 30 or can be subsequently adjusted via the known techniques for doping semiconductor layers.

The free surface of the useful layer 3 is usually rough after separation: for example, its roughness ranges between 5 nm and 100 nm RMS (AFM, 20 microns×20 microns scan). Cleaning and/or smoothing steps can be applied in order to restore a good surface finish (typically, roughness of less than a few angstroms RMS on a 20 micron×20 micron AFM scan).

Alternatively, the free surface of the useful layer 3 can remain rough, as separated, when the following step of the method tolerates this roughness.

In the particular embodiment implementing a second intermediate layer 12′ and a second support layer 2′ disposed on the rear face 1b of the temporary substrate 1, step d) can also comprise transferring a second useful layer 3′ made of c-SiC onto the second support layer 2′, via a second bonding interface 5′ (FIG. 3D).

The manufacturing method according to the present disclosure then comprises a step e) of forming an active layer 4 on the useful layer 3 (FIG. 2E).

Advantageously, the active layer 4 is produced by epitaxial growth of an additional layer made of doped monocrystalline silicon carbide on the useful layer 3. This epitaxial growth occurs in the conventional temperature range, namely between 1,500° C. and 1,900° C., and forms an additional layer that is on the order of 1 micron to several tens of microns thick, depending on the intended electronic components.

The presence of a protective layer on the edges of the intermediate layer 12 made of graphite, in the composite structure 10, is required to prevent the graphite from being damaged by the aforementioned very high temperature treatments. As mentioned above, this protective layer can, for example, be made up of a layer made of polycrystalline silicon carbide (deposited, for example, at the same time as the support layer 2) or an amorphous layer.

The manufacturing method according to the present disclosure can further comprise a step e′) of producing all or some of the electronic components 40 on and/or in the active layer 4 (FIG. 2E′). The electronic components 40 can, for example, be made up of transistors or other high voltage and/or high frequency components.

In order for them to be manufactured on and/or in the active layer 4, conventional steps of cleaning, deposition, lithography, implantation, etching, planarization and heat treatment are carried out. In particular, among the mentioned heat treatments, some are intended to activate dopants locally introduced into the active layer 4 (or the useful layer 3), and are typically carried out at a temperature above or equal to 1,600° C.

It should be noted that in the particular embodiment implementing a second support layer 2′ on the rear face of the temporary substrate 1, step e) can also comprise the formation of a second active layer on the second useful layer 3′; and step e′) can comprise producing all or some second electronic components on and/or in the second active layer.

Finally, the manufacturing method according to the present disclosure comprises a removal step f), at an interface of the intermediate layer 12 and/or in the intermediate layer 12, in order to form, on the one hand, the semiconductor structure 100 including the active layer 4, the useful layer 3 and the support layer 2, and, on the other hand, the temporary substrate 1 (FIG. 2F), and potentially the electronic components 40 (FIG. 2G), if a step e′) has been carried out.

Several alternative embodiments for removal, at the intermediate layer 12 (and potentially at the second intermediate layer 12′, in the particular embodiment) can be implemented for this step.

According to a first alternative embodiment, step f) comprises mechanical removal by propagating a crack in the intermediate layer 12, and/or at the interface between the intermediate layer 12 and the support layer 2, and/or even between the intermediate layer 12 and the temporary substrate 1. The crack propagates substantially parallel to the plane of the intermediate layer 12 following the application of a mechanical stress. For example, inserting a beveled tool opposite the intermediate layer 12 allows an opening to be initiated and propagated at a brittle interface: as graphite has lower cohesive energy along the z-axis, cracking will preferably occur in the intermediate layer 12 or at the interfaces, until there is complete separation between the semiconductor structure 100 and the temporary substrate 1. Advantageously, the protective layer present on the edges 1c of the temporary substrate 1 is removed, by dry or wet etching, for example, in order to promote the initiation of the crack in the graphite.

According to a second alternative embodiment, step f) comprises chemical removal between the semiconductor structure 100 and the temporary substrate 1, by lateral chemical etching. The protective layer (p-SiC) located on the peripheral edges 1c of the temporary substrate 1 (and in particular on the edges of the intermediate layer 12) in the composite structure 10 must be removed chemically or mechanically, in order to allow access to the graphite. Then, the lateral chemical etching of the intermediate layer 12 can implement a solution based on nitric acid and/or sulfuric acid, for example, a solution of concentrated sulfuric acid and potassium dichromate or a solution of sulfuric acid, nitric acid and potassium chlorate. Chemical etching implementing an alkaline solution (of the potassium hydroxide (KOH) or sodium hydroxide (NaOH) type) also can be applied.

Of course, careful attention will be given to the protection of the free face and the edges of the active layer 4 and the electronic components 40 if they are present, and/or to limiting the contact time with the etching solution, in order to avoid damaging them during this chemical removal.

According to a third alternative embodiment, step f) comprises mechanical removal by thermal damage of the graphite forming the intermediate layer 12. Here again, the protective layer present at least on the edges of the temporary substrate 1 needs to be removed in order to provide access to the intermediate layer 12.

Removal by thermal damage can occur at a temperature ranging between 600° C. and 1,000° C., in the presence of oxygen: the graphite of the intermediate layer 12 is then burnt and crumbles, thus separating the semiconductor structure 100 from the temporary substrate 1.

Of course, in the case whereby the electronic components 40 have been produced in step e′), this alternative embodiment of removal can only be applied if the components 40 are compatible with the applied temperature.

According to a fourth alternative embodiment, step f) is carried out by cutting the graphite of the intermediate layer 12 by means of a wire saw. In particular, the wire comprises diamond particles.

It should be noted that the aforementioned alternative embodiments optionally can be combined together in accordance with any technically feasible manner.

Irrespective of the alternative embodiment that is implemented, removal of the temporary substrate 1 can leave residues 12r of the intermediate layer 12 on the rear face 2b of the support layer 2 and/or on the front face of the temporary substrate 1. These residues can be eliminated by mechanical grinding, by chemical-mechanical polishing, by chemical etching and/or by thermal damage.

Chemical-mechanical polishing or chemical etching techniques also can be implemented in order to reduce the roughness of the rear face 2b of the support layer 2, if necessary, following the elimination of the residues 12r.

In the aforementioned particular embodiment, for which a second active layer is present on the side of the rear face 1b of the temporary substrate 1, the step f) of removing the temporary substrate 1 also allows a second semiconductor structure to be formed that includes the second active layer, the second useful layer 3′ and the second support layer 2′.

If the semiconductor structure 100 must be handled during and after the removal of the temporary substrate 1, and its total thickness is insufficient for its mechanical retention during this handling operation, it is possible to contemplate using a detachable handle: the handle is disposed on the active layer 4 or on the components 40, and is temporarily secured thereto, in order to carry out the handling until the singularization step, for example.

The semiconductor structure 100 that is obtained on completion of the manufacturing method according to the present disclosure comprises an active layer 4 advantageously finalized with electronic components 40 and disposed on a support layer 2 with the thickness that is intended for the application. No mechanical thinning involving significant material loss is required. The support layer 2 is made of good quality p-SiC (as it is deposited at relatively high temperatures), but it is low cost compared to a bulk substrate of monocrystalline or polycrystalline SiC, which would have had to be significantly thinned before singularization of the components 40. The temporary substrate 1, after removal, is recovered for recycling, which is also an economic advantage.

The intermediate layer 12 made of graphite allows easy removal of the composite structure 10 after the active layer 4 (and preferably all or some of the components) has been formed, while ensuring mechanical stability of the composite structure 10 during the very high temperature heat treatments applied to produce the active layer 4.

The selection of the physical features of the intermediate layer 12 made of graphite (average grain size, porosity, thermal expansion coefficient) ensures the formation of a support layer 2 allowing a robust and quality composite structure 10 to be obtained, and allowing a reliable and high-performance semiconductor structure 100 to be obtained. The performance of the components 40 particularly arises from the fact that the composite structure 10 allows very high temperature treatments for forming the active layer 4.

The present disclosure also relates to a composite structure 10, previously described with reference to the manufacturing method, and corresponding to an intermediate structure obtained during the method (FIGS. 2D and 3D).

The composite structure 10 comprises:
a temporary substrate 1 made of a material with a thermal expansion coefficient that is close to that of silicon carbide;
an intermediate layer 12 made of graphite, at least disposed on the front face 1a of the temporary substrate 1;
a support layer 2 made of polycrystalline silicon carbide, the thickness of which ranges between 10 microns and 200 microns, disposed on the intermediate layer 12;
a useful layer 3 made of monocrystalline silicon carbide, disposed on the support layer 2.

Preferably, the graphite of the intermediate layer 12 has a grain size ranging between 1 micron and 50 microns, porosity ranging between 6 and 17%, and/or a thermal expansion coefficient ranging between 4×10⁻⁶/° C. and 5×10⁻⁶/° C. The advantages associated with these features have been previously mentioned.

Preferably, the thickness of the useful layer 3 ranges between 100 nm and 1,500 nm. The thickness of the intermediate layer 12 ranges between 1 micron and 100 microns, or between 10 microns and 100 microns; the thickness of the temporary substrate 1 ranges between 300 microns and 800 microns.

For applications for vertical microelectronic components, the support layer 2 advantageously has good electrical conductivity, that is between 0.015 and 0.03 ohm·cm, high thermal conductivity that is greater than or equal to 200 W·m⁻¹·K⁻¹, and a thermal expansion coefficient that is similar to that of the useful layer 3, which is typically between 3.8×10⁻⁶/° C. and 4.2×10⁻⁶/° C. at ambient temperature.

The intermediate layer 12 and/or the temporary substrate 1 advantageously may have thermal conductivity ranging between 5 W·m⁻¹·K⁻¹ and 500 W·m⁻¹·K⁻¹, so as to provide a homogeneous temperature on the temporary substrate 1 during the very high-temperature heat treatment steps of the manufacturing method. In particular, this improves the uniformity of the deposited layers and the reproducibility of the physical properties of the produced layers and components.

Finally, as has been described with reference to the manufacturing method according to the present disclosure, the composite structure 10 can be “double-sided,” i.e., it can comprise:
a second intermediate layer 12′ made of graphite, disposed on the rear face 1b of the temporary substrate 1;
a second support layer 2′ made of polycrystalline silicon carbide, the thickness of which ranges between 10 microns and 200 microns, disposed on the second intermediate layer 12;
a second useful layer 3′ made of monocrystalline silicon carbide, disposed on the second support layer 2′ (FIG. 3D).

Such a composite structure 10 allows two active layers 4 to be formed on the first 3 and the second 3′ useful layer, and, on completion of the manufacturing method according to the present disclosure, it allows two semiconductor structures 100 to be obtained from a single temporary substrate 1.

Of course, the present disclosure is not limited to the embodiments and examples described, and alternative embodiments can be added thereto without departing from the scope of the invention as defined by the claims.

1. A method for manufacturing a semiconductor structure, comprising:
a) providing a temporary substrate of a material with a thermal expansion coefficient ranging between 3.5×10⁻⁶/° C. and 5×10⁻⁶/° C.;
b) forming an intermediate layer of graphite on a front face of the temporary substrate;
c) depositing, onto the intermediate layer, a support layer of polycrystalline silicon carbide, the thickness of which ranges between 10 microns and 200 microns;
d) transferring a useful layer of monocrystalline silicon carbide onto the support layer, directly or via an additional layer, to form a composite structure, the transferring implementing molecular adhesion bonding;
e) forming an active layer on the useful layer; and
f) separating, at an interface of the intermediate layer or in the intermediate layer, to obtain the semiconductor structure including the active layer, the useful layer and the support layer, and the temporary substrate.

2. The method of claim 1, wherein a thickness of the intermediate layer ranges between 1 micron and 100 microns.

3. The method of claim 1, wherein an average grain size of the graphite of the intermediate layer ranges between 1 micron and 50 microns.

4. The method of claim 1, wherein a porosity of the graphite of the intermediate layer ranges between 6 and 17%.

5. The method of claim 1, wherein the graphite of the intermediate layer has a thermal expansion coefficient ranging between 4×10⁻⁶/° C. and 5×10⁻⁶/° C.

6. The method of claim 1, further comprising forming the intermediate layer on a peripheral edge of the temporary substrate; and/or
Forming a second intermediate layer on a rear face of the temporary substrate.

7. The method of claim 1, further comprising depositing the support layer onto an intermediate layer present on a peripheral edge of the temporary substrate and/or directly onto the peripheral edge of the temporary substrate.

8. The method of claim 1, wherein the transferring of the useful layer onto the support layer comprises:
introducing light species into a donor substrate of monocrystalline silicon carbide to form a buried brittle plane defining, with the front face of the donor substrate, the useful layer;
assembling the front face of the donor substrate on the support layer, directly or via an additional layer, by molecular adhesion bonding; and
separating along the buried brittle plane to transfer the useful layer onto the support layer.

9. The method of claim 1, wherein the forming of the active layer on the useful layer comprises epitaxial growth of at least one additional layer of doped monocrystalline silicon carbide on the useful layer, the additional layer forming all or some of the active layer.

10. The method of claim 9, wherein the forming of the active layer on the useful layer further comprises heat treatment at a temperature above or equal to 1,600° C., to activate dopants in the active layer.

11. The method of claim 1, further comprising producing all or some electronic components on and/or in the active layer, prior to the separating.

12. The method of claim 1, further comprising assembling a detachable handle on a free face of the active layer or on a free face of all or some of electronic components formed on and/or in the active layer, prior to the separating.

13. The method of claim 1, wherein:
the separating comprises propagating a crack at an interface of the intermediate layer or in the intermediate layer, following the application of a mechanical stress; and/or
the separating comprises lateral chemical etching of all or some of the intermediate layer; and/or
the separating comprises thermal damage to the graphite of the intermediate layer; and/or
the separating occurs by cutting the graphite of the intermediate layer using a diamond wire saw.

14. The method of claim 6, wherein:
the depositing of the support layer comprises depositing, onto a second intermediate layer present on a rear face of the temporary substrate, a second support layer of polycrystalline silicon carbide, the thickness of which ranges between 10 microns and 200 microns;
the transferring of the useful layer further comprises transferring a second useful layer of monocrystalline silicon carbide onto the second support layer, directly or via an additional layer, the transfer implementing molecular adhesion bonding;
the forming of the active layer comprises forming a second active layer on the second useful layer; and
the separating further comprises separating, at an interface of the second intermediate layer or in the second intermediate layer, to obtain another semiconductor structure including the second active layer, the second useful layer and the second support layer.

15. A composite structure, comprising:
a temporary substrate of a material with a thermal expansion coefficient close to that of silicon carbide;
an intermediate layer of graphite, at least disposed on the front face of the temporary substrate;
a support layer of polycrystalline silicon carbide, the thickness of which ranges between 10 microns and 200 microns, disposed on the intermediate layer; and
a useful layer of monocrystalline silicon carbide, disposed on the support layer.

16. The composite structure of claim 15, wherein the temporary substrate comprises monocrystalline or polycrystalline silicon carbide, and the thickness of the useful layer ranges between 100 nm and 1,500 nm.

17. The method of claim 2, wherein an average grain size of the graphite of the intermediate layer ranges between 1 micron and 50 microns.

18. The method of claim 17, wherein a porosity of the graphite of the intermediate layer ranges between 6 and 17%.

19. The method of claim 18, wherein the graphite of the intermediate layer has a thermal expansion coefficient ranging between 4×10⁻⁶/° C. and 5×10⁻⁶/° C.

20. The method of claim 19, further comprising forming the intermediate layer on a peripheral edge of the temporary substrate; and/or
Forming a second intermediate layer on a rear face of the temporary substrate.
